(19) United States
(12) Patent Application Publication
(10) Pub. No.: US 2025/0311567 A1
(43) Pub. Date: Oct. 2, 2025

(54) ARRAY SUBSTRATE, DISPLAY PANEL AND DISPLAY DEVICE

(71) Applicant: Xiamen Tianma Display Technology Co., Ltd., Xiamen (CN)

(72) Inventors: Jian KUANG, Xiamen (CN); Xingyao ZHOU, Xiamen (CN); Yana GAO, Xiamen (CN)

(21) Appl. No.: 18/965,412

(22) Filed: Dec. 2, 2024

(30) Foreign Application Priority Data
Mar. 29, 2024 (CN) 202410383137.3

(51) Int. Cl. H10K 59/131

(52) U.S. Cl. CPC H10K 59/131

(57) ABSTRACT

An array substrate, a display panel and a display device are provided. The array substrate includes a substrate; a first conductive layer above one side of the substrate; a pixel circuit including a driving transistor and a reset bias transistor; a second conductive layer located on a side of the first conductive layer away from the substrate, and a third conductive layer located on a side of the second conductive layer away from the substrate. The driving transistor and the reset bias transistor are electrically connected through a metal bridge line and the metal bridge line is located on the first conductive layer; a first power line is located on the second conductive layer; and a data line is located on the third conductive layer. In a first direction perpendicular to the substrate, the first power line at least partially covers the metal bridge line.

### CROSS-REFERENCE TO RELATED APPLICATION

This application claims the priority of Chinese Patent Application No. 202410383137.3, filed on Mar. 29, 2024, the content of which is incorporated by reference in its entirety.

### TECHNICAL FIELD

The present disclosure generally relates to the field of display technologies and, more particularly, relates to an array substrate, a display panel and a display device.

### BACKGROUND

With the development of display technologies, the bezel requirements of display panels are getting narrower and narrower. To reduce the bezel of the display panel, there are now a technology to lay out some fan-out lines in the display area.

However, the current display products using this technology have unstable brightness when displaying, and uneven visibility (Mura) will occur under the display state, thus affecting the display quality. The present disclosed array substrates, display panels and display devices are direct to solve such a problem and other problems in the arts.

### SUMMARY

One aspect of the present disclosure provides an array substrate. The array substrate includes a substrate; a first conductive layer above one side of the substrate; a pixel circuit including a driving transistor and a reset bias transistor; a second conductive layer located on a side of the first conductive layer away from the substrate, and a third conductive layer located on a side of the second conductive layer away from the substrate. The driving transistor and the reset bias transistor are electrically connected through a metal bridge line and the metal bridge line is located on the first conductive layer; a first power line is located on the second conductive layer; and a data line is located on the third conductive layer. In a first direction perpendicular to the substrate, the first power line at least partially covers the metal bridge line.

Another aspect of the present disclosure includes a display panel. The display panel includes an array substrate and a light-emitting element. The array substrate includes a substrate; a first conductive layer above one side of the substrate; a pixel circuit including a driving transistor and a reset bias transistor; a second conductive layer located on a side of the first conductive layer away from the substrate, and a third conductive layer located on a side of the second conductive layer away from the substrate. The driving transistor and the reset bias transistor are electrically connected through a metal bridge line and the metal bridge line is located on the first conductive layer; a first power line is located on the second conductive layer; and a data line is located on the third conductive layer. In a first direction perpendicular to the substrate, the first power line at least partially covers the metal bridge line.

Another aspect of the present disclosure includes a display device. The display device includes a display panel. The display panel includes an array substrate and a light-emitting element. The array substrate includes a substrate; a first conductive layer above one side of the substrate; a pixel circuit including a driving transistor and a reset bias transistor; a second conductive layer located on a side of the first conductive layer away from the substrate, and a third conductive layer located on a side of the second conductive layer away from the substrate. The driving transistor and the reset bias transistor are electrically connected through a metal bridge line and the metal bridge line is located on the first conductive layer; a first power line is located on the second conductive layer; and a data line is located on the third conductive layer. In a first direction perpendicular to the substrate, the first power line at least partially covers the metal bridge line.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates the structure of a pixel circuit;

FIG. 2 illustrates the sequence diagram of a pixel circuit;

FIG. 3 illustrates a top view of an exemplary array substrate according to various disclosed embodiments of the present disclosure;

FIG. 4 illustrates a layout structure of an exemplary array substrate according to various disclosed embodiments of the present disclosure;

FIG. 5 illustrates a sequence diagram of an exemplary pixel circuit according to various disclosed embodiments of the present disclosure;

FIG. 6 illustrates a cross-sectional view of an exemplary array substrate according to various disclosed embodiments of the present disclosure;

FIG. 7 illustrates an active layer of an exemplary array substrate according to various disclosed embodiments of the present disclosure;

FIG. 8 illustrates a gate layer of an exemplary array substrate according to various disclosed embodiments of the present disclosure;

FIG. 9 illustrates a capacitor layer of an exemplary array substrate according to various disclosed embodiments of the present disclosure;

FIG. 10 illustrates an oxide transistor layer of an exemplary array substrate according to various disclosed embodiments of the present disclosure;

FIG. 11 illustrates a gate layer of an oxide transistor layer of an exemplary array substrate according to various disclosed embodiments of the present disclosure;

FIG. 12 illustrates a first conductive layer of an exemplary array substrate according to various disclosed embodiments of the present disclosure;

FIG. 13 illustrates a second conductive layer of an exemplary array substrate according to various disclosed embodiments of the present disclosure;

FIG. 14 illustrates a third conductive layer of an exemplary array substrate according to various disclosed embodiments of the present disclosure;

FIG. 15 illustrates a stacked structure of a first conductive layer and a second conductive layer of an exemplary array substrate according to various disclosed embodiments of the present disclosure;

FIG. 16 illustrates a multiple-layer stacked structure of an exemplary array substrate according to various disclosed embodiments of the present disclosure;

FIG. 17 illustrates a multiple-layer stacked structure of another exemplary array substrate according to various disclosed embodiments of the present disclosure;

FIG. 18 illustrates an exemplary pixel array according to various disclosed embodiments of the present disclosure;

FIG. 19 illustrates a second conductive layer of another exemplary array substrate according to various disclosed embodiments of the present disclosure;

FIG. 20 illustrates a stacked structure of a first conductive layer and a second conductive layer of another exemplary array substrate according to various disclosed embodiments of the present disclosure;

FIG. 21 illustrates a multiple-layer stacked structure of another exemplary array substrate according to various disclosed embodiments of the present disclosure;

FIG. 22 illustrates a third conductive layer of another exemplary array substrate according to various disclosed embodiments of the present disclosure;

FIG. 23 illustrates an anode layer stacked structure of an exemplary array substrate according to various disclosed embodiments of the present disclosure;

FIG. 24 illustrates another anode layer stacked structure of an exemplary array substrate according to various disclosed embodiments of the present disclosure; and

FIG. 25 illustrates an exemplary display device according to various disclosed embodiments of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only some of the embodiments of the present disclosure, rather than all of the embodiments. Based on the embodiments in this disclosure, all other embodiments obtained by those of ordinary skill in the art without creative efforts fall within the scope of protection of this disclosure.

Many specific details are set forth in the following description to fully understand the present disclosure. However, the present disclosure can also be implemented in other ways different from those described here. Those skilled in the art can do similar generalizations without violating the connotation of the present disclosure, and therefore the present disclosure is not limited to the specific embodiments disclosed below.

Secondly, the present disclosure will be described in detail in conjunction with schematic diagrams. When describing the embodiments of the present disclosure in detail, for the convenience of explanation, the cross-sectional diagram showing the device structure will not be partially enlarged according to the general scale, and the schematic diagrams are only examples and should not limit the scope of protection of this disclosure. In addition, the three-dimensional dimensions of length, width and depth should be included in actual production.

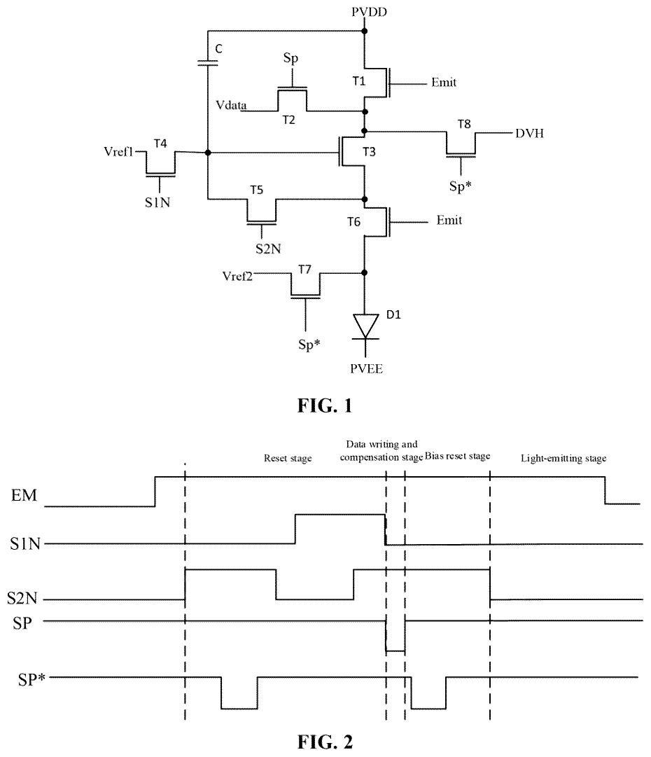

FIG. 1 illustrates a pixel circuit. The pixel circuit includes eight transistors and a storage capacitor. Among them, the first terminal of the data writing transistor T2 is used to receive the data signal during the data writing stage, and the second terminal is connected to the second terminal of the reset bias transistor T8 and the first terminal of the driving transistor T3. The gate of the data writing transistor T2 is connected to the second scanning signal SP*, and under the action of SP*, the data signal is written to the gate of the driving transistor T3. The reset bias transistor T8 can, in the reset bias phase, write a reset bias signal to the driving transistor T3 to adjust the gate potential of the driving transistor T3 to realize multiple bias adjustments for the driving transistor T3. The first terminal of the reset bias transistor T8 is used to receive the reset bias signal during the reset bias stage, and the second terminal of the reset bias transistor T8 is electrically connected to the second terminal of the data writing transistor T2 and the first terminal of the driving transistor T3. The first terminal of the threshold compensation transistor T5 is connected to the second terminal of the driving transistor T3, and the second terminal is connected to the gate of the driving transistor T3. The gate of the threshold compensation transistor T5 is connected to the third scanning signal S2N to realize the threshold compensation of the driving transistor T3 under the action of S2N. The first terminal of the first initialization transistor T4 is used to connect the first initialization signal Vref1, the second terminal of the first initialization transistor T4 is connected to the gate of the driving transistor T3, the gate of the first initialization transistor T4 is connected to the fourth scanning signal S1N, and the signal Vref1 is written to the gate of the driving transistor T3 under the control of the fourth scanning signal S1N to achieve the initialization of the driving transistor T3. The first terminal of the second initialization transistor T7 is used to connect the second initialization signal Vref2, the second terminal of the second initialization transistor T7 is connected to the anode of the light-emitting element D1, the gate of the second initialization transistor T7 is connected to the first scan signal SP, and under the action of SP, the Vref2 signal is written to the anode to initialize the anode. The first terminal of the first light-emitting control transistor T1 is used to connect to a power supply signal PVDD, the second terminal of the first light-emitting control transistor T1 is connected to the second terminal of the data writing transistor T2, and the second terminal of the reset bias transistor T8 and the first terminal of the driving transistor T3 respectively. The gate of the first light-emitting control transistor T1 is used to access the light-emitting control signal Emit, the first terminal of the second light-emitting control transistor T6 is connected to the second terminal of the driving transistor T3, and the second terminal of the second light-emitting control transistor T6 is connected to the anode of the light-emitting element D1. The gate of the second light-emitting control transistor T6 is used to access the light-emitting control signal Emit, under the action of the light-emitting control signal, T3 and T6 write the driving current to the light-emitting element D1 to realize the lighting of the light-emitting element. The above is only an introduction to each transistor and light-emitting element in the pixel circuit, and does not represent the specific working process.

FIG. 2 shows the operation sequence of the pixel circuit in FIG. 1. The configuration that the first initialization transistor T4 and the threshold compensation transistor T5 in the pixel driving circuit are oxide transistors (Indium Gallium Zinc Oxide, IGZO), that is, The configuration that the first initialization transistor T4 and the threshold compensation transistor T5 are N-type transistors and the remaining transistors are P-type transistors is used for the description.

As shown in FIG. 2, a driving cycle of the pixel driving circuit may include a reset stage, a data writing and compensation stage, a reset bias stage, and a light-emitting stage.

The reset stage includes the period when the EM signal is at high-level, S2N is at high-level, S1N is at low-level, SP* is at low-level, and SP is at high-level. At this time, the transistors T1, T2, T4, and T6 are turned off, and T5 and T7 are turned on. The light-emitting element D1 is off, the Vref2 signal is written into the anode of D1, and the anode of D1 is reset. After that, the reset stage also includes the period when the EM signal is at high-level, S1N is at high-level, S2N is at low-level, and SP* is at high-level. At this time, T1, T2, T5, and T6 are turned off, T4 is turned on, the Vref1 signal is written to T3, and the gate of T3 is reset.

In the data writing and compensation stage, EM is at high-level, S1N is at low-level, S2N is at high-level, SP is at low-level, SP* is at high-level, transistors T1, T4, and T6 are turned off, T2, T3, and T5 are turned on, Vdata is written to the gate of T3, and the Vdata signal keeps charging to the gate of T3 through T5 until T3 is turned off. At this time, the voltage difference between the gate and the source of T3 is the threshold voltage, thus realizing the data writing and threshold compensation of T3.

In the reset bias stage, SP* is at low-level, S2N is at high-level, and S1N is at low-level. At this time, transistors T3, T5, and T8 are turned on, and the reset bias signal DVH is written to the gate of the driving transistor T3 through T8, and T5 to adjust the gate potential of the driving transistor T3.

In the light-emitting stage, the EM signal is at low-level, S1N is at low-level, S2N is at low-level, SP is at high-level, and SP* is at high-level, the transistor T8 is turned off, T1, T3, and T6 are turned on, and the light-emitting element D1 emits light.

The types of transistors in the pixel drive circuit are diverse, oxide transistors (Indium Gallium Zinc Oxide, IGZO) and low-temperature polysilicon transistors (LTPS) can coexist. The oxide transistors have advantages including small leakage current, etc., and the low-temperature polysilicon transistors have advantages including high switching speed, high carrier mobility and low power. The low temperature polycrystalline oxide (LTPO) display panel technology combines LTPO and IGZO, not only has the advantages of high resolution, high response speed, high brightness and high aperture ratio of LTPS display panels, but also has the advantage of small leakage current of IGZO.

In addition, the threshold compensation transistor T5 and the first initialization transistor T4 may be single-gate transistors or double-gate transistors. When a double-gate transistor is used, the leakage current of the transistor is reduced and the display effect of the display panel is improved. The present disclosure only takes both the threshold compensation transistor T5 and the first initialization transistor T4 are top-bottom dual-gate transistors as an example.

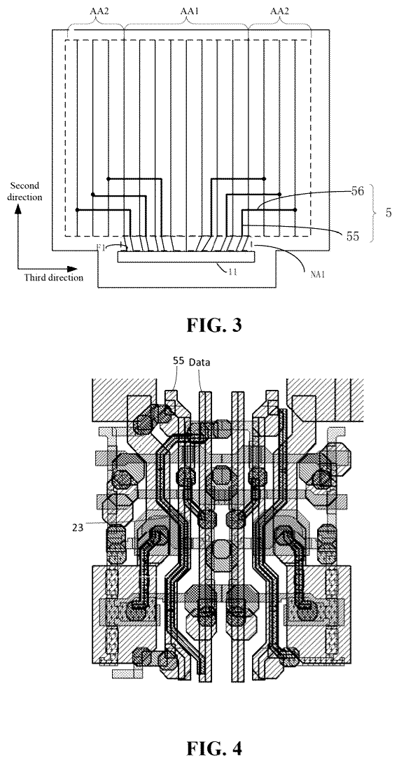

FIG. 3 is a schematic diagram of an exemplary array substrate according to various disclosed embodiments of the present disclosure. As shown in FIG. 3, an array substrate may include a display region (not labelled) and a non-display region (not labeled) surrounding the display region. A driving chip 11 may be provided in the non-display region. The driving chip 11 may provide driving signals and data signals. The non-display region may also include a fan-out region NA1, and NA1 may include a fan-out line F1. The display region may include at least two sub-display regions AA1 and AA2. A fan-out data line 5 may be located in the display regions (AA1 and AA2). The fan-out data line 5 may include a first line segment 55 extending in the second direction and a second line segment 56 extending in the third direction. The first line segment 55 and the second line segment 56 may be arranged on the same layer or on different layers. The AA2 region may be adjacent to the bezel region of the array substrate. The data lines in the sub-display region AA2 region may be electrically connected to the fan-out line F1 in the fan-out region NA1 through the fan-out data line 5. The fan-out line may be electrically connected to the driving chip 11, which may save the area of the NA1 region and achieve the effect of narrow bezel. The second direction and the third direction may intersect each other, the data lines in a subsequently described third conductive layer of the array substrate may extend in the second direction. The first line segment 55 may be located in the third conductive layer, and the second line segment 56 may be connected to the corresponding data line.

FIG. 4 illustrates a schematic diagram of the film layer structure of the position containing both the data line and the fan-out data line in the AA1 region in FIG. 2. Data may be the normal data line in the AA1 region, 55 may be the first line segment of the fan-out line connecting the data lines in the AA2 region, and Data and 55 may be adjacent to each other and may be disposed in the same conductive layer, for example, the third conductive layer. FIG. 2 also shows a metal bridge line 23. Other metal lines will be described later. The metal bridge line 23 may connect the driving transistor T3 and the reset bias transistor T8, and the details may be referred to FIG. 8. The active layer of the reset bias transistor T8 may not be connected to the active layer of the driving transistor T3, and then the current of the voltage through T1 may not be transferred to T3 smoothly, and the light-emitting element D1 cannot emit light normally. Therefore, T1 and T3 may be electrically connected by providing a metal bridge line 23, thereby realizing the normal light-emission of the light-emitting element D1. The metal bridge line 23 may be located between the active layer and the third conductive layer. It can be seen from FIG. 2 that in the direction perpendicular to the display panel, the metal bridge line 23 and the first line segment 55 may partially overlap, and a parasitic capacitance may be generated between them. When the potential on the first line segment 55 changes, the potential of the metal bridge line 23 may change due to the coupling effect of the parasitic capacitance, thereby affecting the display effect of the area where the pixel circuit is located.

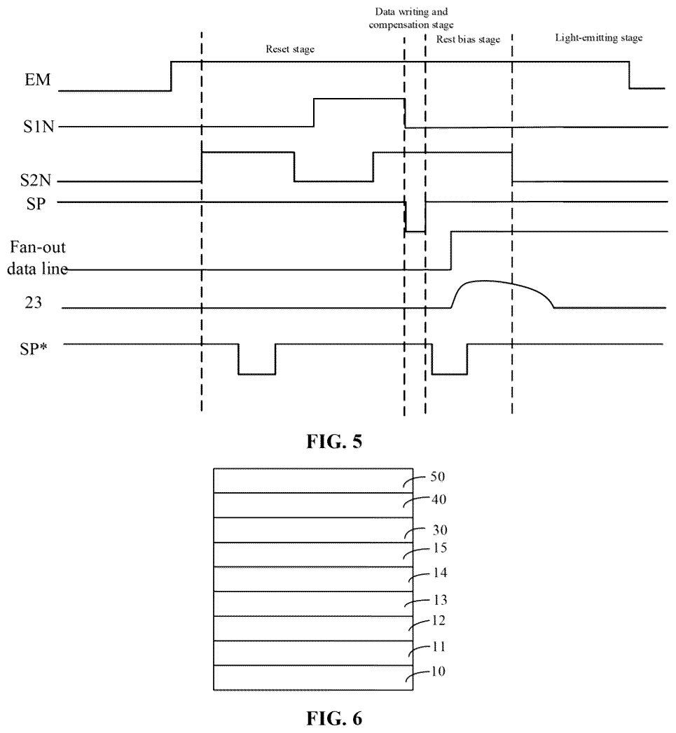

Further, as shown in FIG. 5, which shows the time sequence when the metal bridge line 23 is affected by the potential of the fan-out data line. Compared with the time sequence in FIG. 4, the potential changes of the fan-out data line and the N1 node are added, the rest may be same as FIG. 4, will not be described again.

In the data writing stage, the data writing transistor T2 may be turned on under the action of Sp, and the data signal may be written to the gate of the driving transistor T3. When the potential in the fan-out data line in the AA1 region changes, it may be coupled to the metal bridge line 23 in the AA1 region, causing the potential on the metal bridge line 23 in the AA1 region to change, and the potential on the metal bridge line 23 may jump high. At the same time, the S2N signal that controls the on-off of the threshold compensation transistor may not been completely turned off. Therefore, the potential on the metal bridge line 23 may be written to the gate of the driving transistor T3 through the threshold compensation transistor. In the light-emitting stage, as the first and second light-emitting control transistors may be turned on, the affected light-emitting elements in the AA1 region may be turned on, resulting in bright/dark stripes and uneven display, and affecting the display effect of the AA1 region.

The present disclosure provides an array substrate. The array substrate may include a substrate and a pixel circuit. The pixel circuit may include a driving transistor and a reset bias transistor. The driving transistor and the reset bias transistor may be electrically connected through a metal bridge line. The metal bridge line may be located on a first conductive layer. The array substrate may also include a second conductive layer. The second conductive layer may be located on the side of the first conductive layer away from the substrate. A first power line may be located on the second conductive layer. Further, the array substrate may include a third conductive layer. The third conductive layer may be located on the side of the second conductive layer away from the substrate. A data line may be located on the third conductive layer. In a first direction that is perpendicular to the plane of the substrate, the first power line may cover at least a portion of the metal bridge line.

Specifically, the array substrate may include a substrate and a pixel circuit. The pixel circuit may include a driving transistor and a reset bias transistor. The driving transistor and the reset bias transistor may be electrically connected through a metal bridge line, and the metal bridge line may be located on the first conductive layer. The array substrate may also include a second conductive layer. The second conductive layer may be located on a side of the first conductive layer away from the substrate, and a first power line may be provided on the second conductive layer. The array substrate may also include a third conductive layer. The third conductive layer may be located on a side of the second conductive layer away from the substrate, and a data line may be provided on the third conductive layer. In a first direction perpendicular to the plane of the substrate, the first power line may cover at least a portion of the metal bridge line. Using such an array substrate, because the DC power signal may pass through the first power line, the first power line may be isolated between the at least portion of the metal bridge line and the third conductive layer, the first power line may play an isolation role, isolating the at least portion of the metal bridge line and the first line segment extending in the second direction of the fan-out data line on the third conductive layer, thereby reducing the parasitic capacitance between the metal bridge line and the first line segment on the third conductive layer, preventing the potential of the metal bridge line from being affected by the first line segment on the third conductive layer, making the potential of the metal bridge line more stable, improving the stability of the current in the pixel circuit and ensuring the stability of the display screen of the array substrate.

The above is the core idea of the present disclosure. The technical solutions in the embodiments of the present disclosure will be clearly and completely described below with reference to the drawings in the embodiments of the present disclosure. Based on the embodiments of the present disclosure, all other embodiments obtained by those of ordinary skill in the art without creative efforts fall within the scope of protection of the present disclosure.

One embodiment of the present disclosure provides an array substrate. FIG. 6 illustrates the layer structure of an exemplary array substrate according to various disclosed embodiments of the present disclosure. As shown in FIG. 6, the array substrate may include a substrate 10 and multiple layers stacked sequentially in a direction away from the substrate 10. The multiple layers may include an active layer 11, a gate layer 12, a capacitor layer 13, an oxide transistor (Indium Gallium Zinc Oxide, IGZO) layer 14, an oxide transistor gate layer 15, a first conductive layer 30, a second conductive layer 40, and a third conductive layer 50. An insulation layer may be disposed between each of the above multiple layers. The insulation layer may be an organic layer or an inorganic layer, which is not shown here. The substrate 10 may include a first base layer (made of polyimide), a first barrier layer, and a second barrier layer (made of a-Si) stacked in sequence. The substrate 10 may provide a support for the remaining structural layers disposed thereon. In some embodiments, the substrate 10 may be a rigid substrate 10, and the material of the rigid substrate 10 may be glass. The substrate 10 may also be a flexible substrate. The material of the flexible substrate 10 may include at least one of polyimide (PI), polyethylene terephthalate, polyethylene naphthalate, polyethylene, polyacrylate, polyetherimide, polycarbonate, polyarylate and polyethersulfone.

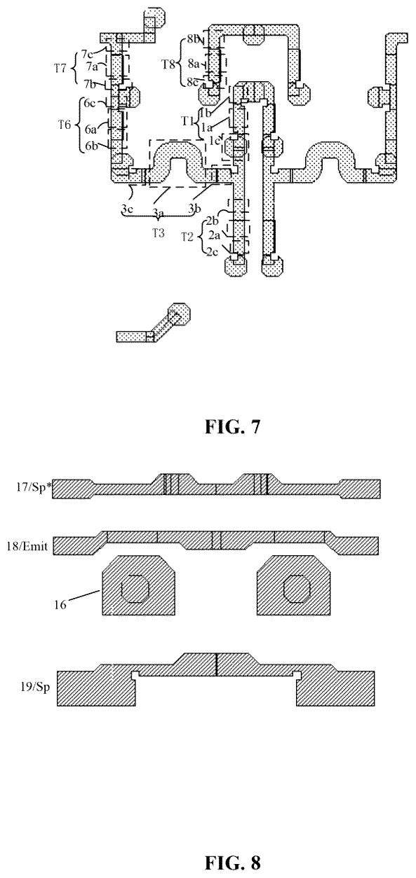

FIG. 7 is a schematic diagram of an exemplary active layer 11 of the array substrate. As shown in FIG. 7, the active layer 11 may include the active regions of multiple transistors in the pixel circuit. Specifically, the active regions of the transistors T1, T2, T3 T6, T7 and T8 may all be located on the active layer 11. For example, the channel region 1a, the source region 1b and the drain region 1c of the transistor T1, the channel region 2a, the source region 2b and the drain region 2c of the transistor T2, the channel region 3a, the source region 3b and the drain region 3c of the transistor T3, the channel region 6a, the source region 6b, the drain region 6c of the transistor T6, the channel region 7a, the source region 7b of the transistor T7, and the drain region 7c of the transistor T7, and the channel region 8a, the source region 8b and the drain region 8c of the transistor T8 may be all on the active layer 11. The above-mentioned transistors including T1, T2, T3, T6, and T7 may be connected through the active layer 11, that is, the polysilicon semiconductor layer. For example, the first light-emission control transistor T1 may be electrically connected to the driving transistor T3. In FIG. 7, the active layer of the reset bias transistor T8 may not be connected to the active layers of other transistors. FIG. 7 includes the active layers of two pixel circuits; the reset bias transistors T8 of the two adjacent pixel circuits may be electrically connected together; and the electrical connection between the active layers of the first light-emitting control transistors T1 in two adjacent pixel circuits may be achieved. Such a design may reduce the locations of via holes and improve the convenience of operation. Because the designs of adjacent pixel circuits may be the same or similar, the explanations of schematic diagrams involving specific layers in the following are usually focused on one of the pixel circuits.

FIG. 8 is a schematic diagram of the gate layer 12 of an exemplary array substrate according to various disclosed embodiments of the present disclosure. As shown in FIG. 8, the gate layer 12 may include the gate 16 of the driving transistor T3. At the same time, a portion of the gate 16 may also serve as the lower plate of the storage capacitor C. The gate layer 12 may also include a scanning signal line Sp*/17 controlling the conduction of the reset bias transistor T8 and the second initialization transistor T7. Further, the gate layer 12 may include the light-emitting control signal line Emit/18 controlling the conduction of the first light-emitting control transistor T1 and the second light-emitting control transistor T2. Further, the gate layer may include a scanning signal line Sp/19 controlling the conduction of the data writing transistor T2.

FIG. 9 is a schematic diagram of the capacitor layer 13 of an exemplary array substrate according to various disclosed embodiments of the present disclosure. As shown in FIG. 9, the capacitor layer 13 may include a second plate 24 of the capacitor C in the pixel circuit, and a plurality of signal lines including the first scanning signal line S1N/25, the second scanning signal line S2N/22 and the second initialization signal line Vref2/21. The first scanning signal line S1N/25 may be connected to the gate of the threshold compensation transistor T4, the second scanning signal line S2N/22 may be connected to the gate of the first reset transistor T5, and the second initialization signal line Vref2/211 may be connected to one terminal of the second reset transistor T7 to realize the reset of the anode. The threshold compensation transistor T4 and the first reset transistor T5 may be dual-gate transistors, and the first scanning signal line 25 and the second scanning signal line 22 may be electrically connected to the bottom gates of the threshold compensation transistor T4 and the first reset transistor T5, respectively.

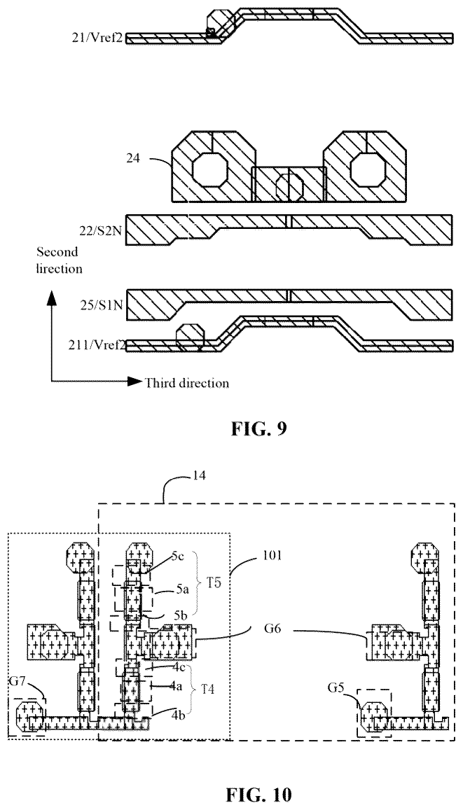

FIG. 10 is a schematic diagram of the IGZO layer 14 of an exemplary array substrate according to various disclosed embodiments of the present disclosure. FIG. 10 also shows the second initialization signal line Vref2/211, which may be a second initialization signal line in an adjacent pixel circuit. FIG. 12 is a schematic diagram of the first conductive layer 30 of the array substrate. The arrangement and connection of the IGZO layer and the first conductive layer may be understood by combining FIG. 10 and FIG. 12.

As shown in FIG. 10, the IGZO layer 14 may include the IGZO transistors T4 and T5 in the pixel circuit. The gate region 4a, the source region 4b and the drain region 4c of the transistor T4, and the gate region 5a, the source region 5b and the drain region 5c of the transistor T5 are shown in FIG. 10. The IGZO layer may be the oxide semiconductor layer.

As shown in FIG. 12, the first conductive layer 30 may include the source and drain electrodes of the plurality of transistors in the pixel circuit and the metal pad layer of the anodes, some of which are not shown with reference numbers. The first conductive layer 30 may also include the first initialization signal line Vref1/29, the second initialization signal connection line Vref2/31, the connection structure 33, and the metal bridge line 23, etc. The region 14 in FIG. 10 may be at the same position as the pixel circuit shown in the schematic diagrams in other film layers. For example, the region 14 may be combined with the region 141 in FIG. 12 to understand the connection of the signal lines. The region 14 in FIG. 10 may include the design scenario of the oxide semiconductor layer of the transistors T4 and T5 of the adjacent pixel circuits. The source region 5c and the drain region 4c may be electrically connected through the oxide semiconductor layer, and may be electrically connected to the gate of the driving transistor T3 through the connection structure 33 at the position G6 so as to transmit the signal to the gate of the driving transistor T3 to realize the functions of resetting or threshold compensation of the driving transistor when T4 or T5 is turned on.

It can be seen from FIG. 10 that the transistors T4 and T5 of two adjacent pixel circuits may be electrically connected together, and the details may be referred to the region 101. The region 101 may include two first reset transistors and two threshold compensation transistors; and the two first reset transistors may be electrically connected through an oxide semiconductor layer. It can be understood that the oxide semiconductor layer of the first reset transistor T4 on the right side of the region 14 may also be electrically connected to the first reset transistor T4 in the pixel circuit on the right side.

It can be seen from FIG. 12 that the first initialization signal lines Vref1/29 may extend in the second direction and may be arranged along the third direction. The region 14 of FIG. 10 may also include a region G5, and the region 141 of FIG. 12 may include a region G51. The region G5 and the region G51 may be provided via holes to electrically connect the first initialization signal line 29 to the first reset transistor T4 such that the first initialization signal may be transmitted to the first reset transistor T4 to achieve the gate reset of the driving transistor T3. Therefore, it can be understood that the first reset transistor T4 on the left side of the region 14 may be electrically connected to the first reset signal line in the G7 region.

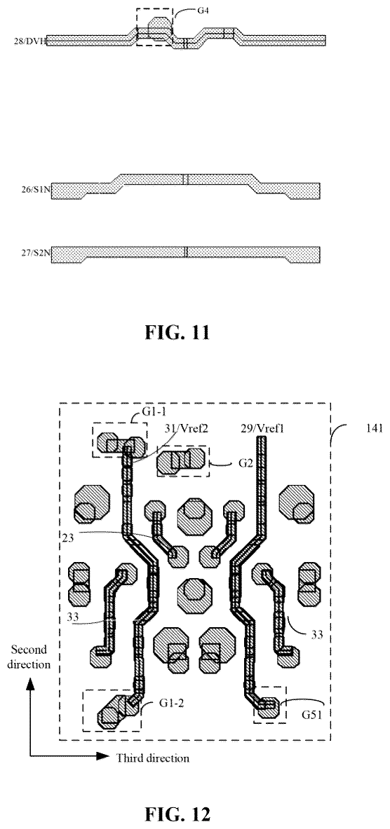

FIG. 11 is a schematic diagram of the oxide transistor gate layer 15 of the array substrate. The oxide transistor gate layer 15 may include the reset bias signal line DVH/28, the first scanning signal line S1N/26 and the second scanning signal line S2N/27. The first scanning signal line S1N/26 and the second scanning signal line S2N/27 may be electrically connected to the top gate of the threshold compensation transistor T5 and the first reset transistor T4 respectively, and the reset bias signal line DVH/28 is in the region G4 may be electrically connected to the source region 8b of the reset bias transistor T8 through a via hole.

FIG. 12 also shows a second initialization signal connection line Vref2/31 and the metal bridge line 23. The metal bridge line 23 may be electrically connect the source of the driving transistor T3 and the drain of the reset bias transistor T8 to write the reset bias signal to the gate of the driving transistor T3 to realize the bias reset for the driving transistor T3 at certain times. The second initialization signal connection lines Vref2/31 may extend in the second direction and may be arranged along the third direction, and may be used to connect two adjacent second initialization signal lines extending in the third direction and arranged in the second direction.

It can be understood from FIG. 9 and FIG. 12 that FIG. 9 may include two second initialization signal lines, namely the second initialization signal line Vref2/21 and the second initialization signal line Vref2/211, which may be connected to the second initialization transistors T7 of two adjacent pixel circuits respectively to realize the reset of the anode. The second initialization signal connection line Vref2/31 may be electrically connected to the second initialization signal line Vref2/21 and the second initialization signal line Vref2/211 through via holes at the positions of the region G1-1 and the region G1-2 to forming a grid to reduce the voltage drop of Vref2 and improve the stability of display. The second initialization signal connection line Vref2/31 and the first initialization signal line Vref1/29 in FIG. 12 may be arranged in the third direction.

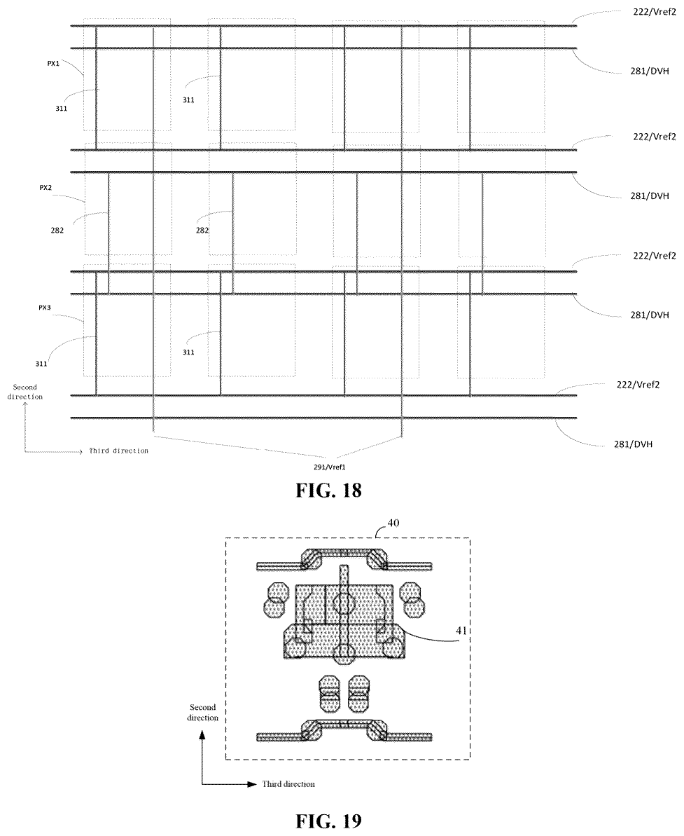

Furthermore, the arrangement of each metal line in the first conductive layer 30 in the array substrate may also be understood in conjunction with FIG. 12 and FIG. 18. FIG. 12 is a schematic diagram of the first conductive layer 30 of the array substrate; and FIG. 18 is a schematic diagram of an exemplary pixel array, which includes the arrangement of the reset bias signal line DVH/281, the first initialization signal line Vref1/291, the second initialization signal line Vref2/222, the second initialization signal connection line 311 and the reset bias signal connection line 282 in the array substrate. In FIG. 12, the second initialization signal connection lines Vref2/31 and the first initialization signal lines Vref1/29 may be alternately arranged in the third direction on the first conductive layer 30. In FIG. 18, PX1, PX2, and PX3 are pixel circuits, which may be defined by each transistor in the pixel circuits and signal lines electrically connected to the transistors. The pixel circuits may be arranged in the second direction to form pixel columns, and a plurality of pixel circuits may be arranged in the third direction to form pixel rows. The second initialization connection line 311 and the first initialization signal line 291 may extend in the second direction and may be arranged in the third direction. A same initialization signal line 291 may be electrically connected to two adjacent columns of pixel circuits arranged in the third direction. The second initialization connection lines 311 may be arranged in the third direction and may be used to connect two adjacent second initialization signal lines 222/Vref2 to reduce the voltage drop of the second initialization signal and improve the stability of the display panel.

FIG. 18 also includes a plurality of reset bias signal connection lines 282, which may be used to connect two adjacent reset bias signal lines DVH/28 to reduce the voltage drop of the reset bias signal and improve the stability of the display panel. Among them, along a direction of a same pixel column, the second initialization signal connection line 311 and the reset bias signal connection line 282 may be arranged alternately. Specifically, referring to FIG. 18, the second initialization signal connection line 311 may be connected to the second initialization signal Vref2/222 in PX1 and PX2, while the reset bias signal connection lines 282 alternatively distributed in the column direction of the second initialization signal connection lines 311 may connect the two reset bias signal lines 281/DVH in the adjacent pixel circuits PX2 and PX3, and so on, forming an alternating arrangement in the second direction. In FIG. 18, for the same pixel row, multiple second initialization signal connection lines 311 may be arranged sequentially in the third direction to realize multiple electrical connections between two adjacent second initialization signal lines Vref2/222, and reduce the voltage drop and improve the display stability.

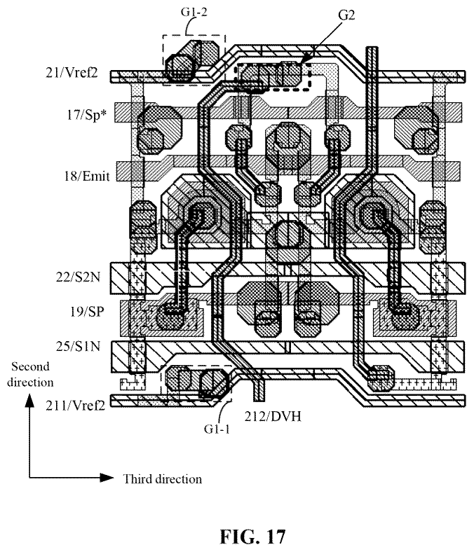

FIG. 17 illustrates an exemplary setting of the reset bias signal connection lines in the pixel circuit. The pixel circuit may include an active layer, a gate layer, a capacitor layer, an IGZO layer, an oxide transistor (Indium Gallium Zinc Oxide, IGZO) layer, and an oxide transistor gate layer and a first conductive layer that are stacked. The reset bias signal connection line DVH/212 may be electrically connected to the reset bias signal line in the gate layer of the oxide transistor through the via hole in the G2 region, thereby reducing the voltage drop of the reset bias signal and improving the display stability. It can be seen that the difference from FIG. 12 may be that FIG. 17 may include the reset bias signal connection line 212 and does not include the second initialization signal connection line. However, in FIG. 17, it can be seen that the second initialization signal lines Vref2/21 and Vref2/211 may be provided with G1-2 and G1-1 regions, and such two regions may be respectively used to achieve the electrical connection between the second initialization signal connection line and the second initialization signal line adjacent the reset bias signal connection lines 212. By arranging multiple second initialization signal lines and multiple reset bias signal lines alternately in the second direction, it may be equivalent to using a part of the space to arrange the second initialization signal connection lines and the other part of the space to arrange the reset bias signal line in the second direction, thus saving wiring space. At the same time, a second initialization signal connection line may be used to connect two adjacent second initialization signal lines extending in the third direction, and a reset bias signal connection line may be used to connect two adjacent reset bias signal lines extending in the third direction, the voltage drop on the second initialization signal line and the reset bias signal line may be reduced, and the accuracy and consistency of signal transmission may be improved.

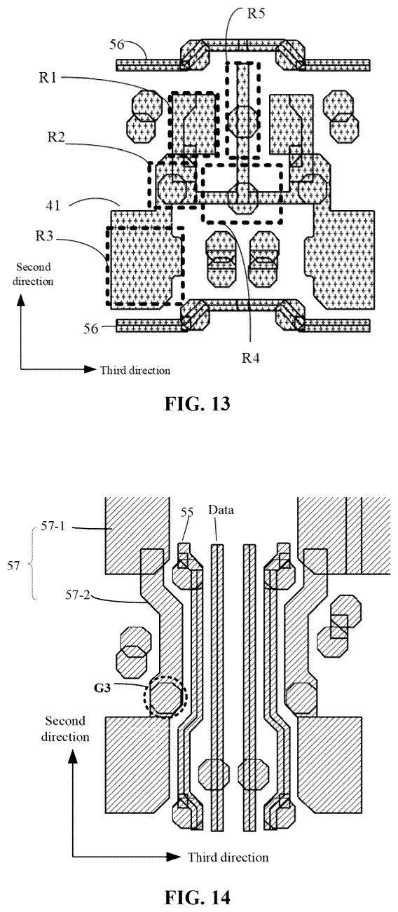

FIG. 13 is a schematic diagram of the second conductive layer 40 of the array substrate. The second conductive layer 40 may include a first power line 41; and the first power line 41 may include the first to fifth regions. The first power line 41 may be electrically connected to the active layer of the first light-emitting control transistor T1 in the fifth region through a via hole, and electrically connected to the upper plate 24 of the storage capacitor C in the fourth region through a via hole. The first power line 41 may be electrically connected to the first light-emitting control transistors in two adjacent pixel circuits. It can be seen from FIG. 13 that the first power line 41 connecting the two adjacent pixel circuits may be symmetrically designed, thereby reducing the area of the first conductive line, reducing the number of via holes between the first conductive line, the lower active layer and the upper plate 24, reducing the process difficulty and improving the process reliability. The second conductive layer 40 may also include a second line segment 56 extending in the third direction. The second conductive layer 40 may be electrically connected to the data line in the AA2 region and the first line segment 55 in the AA1 region.

FIG. 14 is a schematic diagram of the film layer of the third conductive layer 50 of the array substrate. The third conductive layer 50 may include the data line Data of the array substrate and the first line segment 55 of the fan-out data line. The data line Data and the first line segment 55 may all extend in the second direction and be arranged in the third direction. It can be understood by referring to FIG. 3 that the data line Data and the first line segment 55 may be located in the display region AA1. The data line Data may be a data line in the display region AA1, and the first line segment 55 may be electrically connected to the second line segment 56 and may be used to transmit the data signal to the data line located in the display region AA2. The third conductive layer 50 may also include a second power line 57. The second power line 57 may be electrically connected to the first power line 41 in the second conductive layer 40 through a via hole at the position G3. The power signal in the second power line 57 may be written to the first light-emitting control transistor T1 and the upper plate of the storage capacitor C. The electrical connection between the first power line 41 and the second power line 57 may reduce the voltage drop of the power signal and improve the stability of the panel. The second power line 57 may include a first part 57-1 and an adjacent second part 57-2. The width of the first part 57-1 may be greater than the width of the second part 57-2, thereby improving the transparency of the display panel, and reduce the impact on the fingerprint sensor, and there may be space to realize the placement of the anode pad. The second power line 57, the first line segment 55 and the data line Data may be arranged sequentially in the third direction. Because of the symmetrical design of the active layers in the two adjacent pixel circuits, the arrangement of the above-mentioned metal lines may also be a symmetrical design. It can be seen from FIG. 13 and FIG. 14 that the first power line 41 may at least partially overlap the data lines of two adjacently arranged pixel circuits, which may maximize the panel design and improve the display panel resolution. The power line here may include multiple branch structures and may not be a smooth line in the conventional sense.

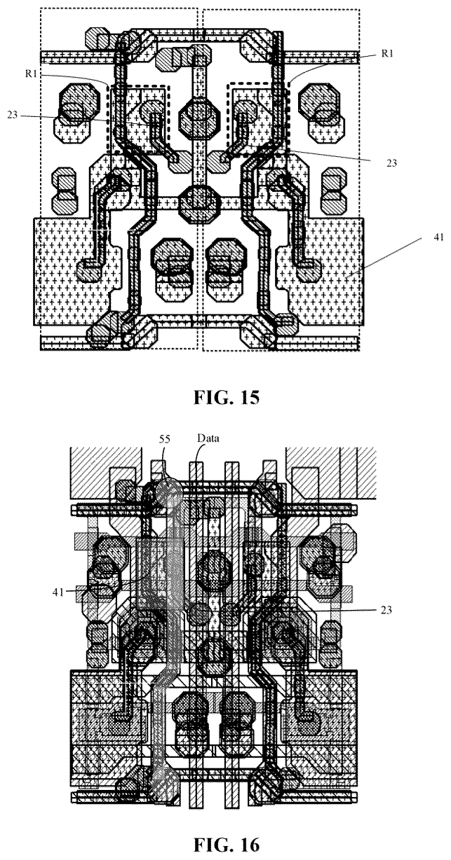

FIG. 15 is a schematic diagram of the stacked structure of the first conductive layer 30 and the second conductive layer 40. The first region R1 of the first power line 41 may achieve at least a partial coverage of the metal bridge line 23 in the first direction perpendicular to the display panel. To more intuitively show that the first power line 41 in the first region R1 covers at least a part of the metal bridge line 23 in FIG. 15, only the first conductive layer and the second conductive layer are shown in FIG. 15. The metal bridge line 23 may be used to electrically connect the reset bias transistor T8 and the active layer of the driving transistor T3 to write the bias signal DVH to the gate of the driving transistor, thereby realizing the bias adjustment of the gate of the driving transistor. As can be seen in FIG. 15, the first region R1 of the first power line 41 may cover the metal bridge line 23. The coverage of the first power line may include that the first power line 41 may completely cover the metal bridge line 23 or cover at least a part of the metal bridge line 23 in the direction perpendicular to the array substrate. However, whether it is fully covered or at least partially covered, the first power line 41 may shield the metal bridge line 23 and reduce the impact of potential changes of metal lines in other film layers far away from the first power line 41 on the potential of the metal bridge line 23, improving the stability of the corresponding pixel circuit.

FIG. 16 shows a multiple-layer stacked structure of an exemplary array substrate according to various disclosed embodiments of the present disclosure. As shown in FIG. 16, the array substrate may include an active layer, a gate layer, a capacitor layer, an IGZO layer, an oxide transistor gate layer, a first conductive layer, a second conductive layer, and a third conductive layer stacked together. In the stacking diagram, to easily distinguish the first line segment 55, the first power line 41, and the metal bridge line 23, different colors are used to mark the above three metal lines. It can be seen that the first line segment 55 (indicated by a first shadow, e.g., in yellow color) of the fan-out data line may be located above the first power line 41 (indicated by a second shadow, e.g., in green color), that is, in the first direction perpendicular to the substrate, the first line segment 55 and the first power line 41 may at least partially overlap. Therefore, the parasitic capacitance between the first line segment 55 and the metal bridge line 23 may be reduced, thereby reducing the impact of potential changes in the first line segment 55 on the underlying metal lines such as the metal bridge line 23 of the first power line 41; and the display stability may be improved.

Therefore, by arranging the first power line 41 to at least partially cover the metal bridge line 23 and isolate the first line segment 55 extending in the second direction and within at least a part of the metal bridge line 23 and the fan-out data line on the third conductive layer 30, the parasitic capacitance between the metal bridge line 23 and the first line segment 55 on the third conductive layer 30 may be reduced; and the potential on the metal bridge line 23 may be prevented from being affected by the first line segment 55 on the third conductive layer 30. Accordingly, the potential of the metal bridge line 23 may be more stable, which may improve the stability of the current in the pixel circuit and ensure the stability of the display screen on the array substrate.

Further, referring to FIG. 16, in the first direction perpendicular to the substrate, there may be an overlapping region S1 between the metal bridge line 23 (indicated by a third shadow, e.g., in red color) and the first line segment 55 (indicated by the first shadow, e.g., in yellow color). The first power line 41 (indicated by the second shadow, e.g., in green color, only the first region R1 in FIGS. 13 and 14 is shown) may include a first region R1. The first region may cover the overlapping region S1. Therefore, compared to the solution in which the first power line is not provided, the first region may cover the overlapping area of the metal bridge line 23 and the first line segment 55, which may further improve the potential stability of the metal bridge line 23, avoid the influence of the potential change of the first line segment 55 on the metal bridge line 23, improve the display stability, and reduce display unevenness. The power line 41 may isolate at least parts of the metal bridge line 23 and the first line segment 55.

In one embodiment, referring to FIG. 13, the first power line 41 may include a second region R2 that at least partially covers the channel region of the driving transistor T3 in the first direction. Specifically, the second region R2 of the first power line 41 may at least partially cover the channel region of the driving transistor T3 in the first direction (the direction perpendicular to the substrate), thereby achieving the shielding of the channel region of the driving transistor T3, preventing light in the external environment from affecting the driving transistor T3 and preventing the driving transistor T3 from changing its characteristics due to external light, making the potential of the driving transistor more stable, and improving the stability of the display screen.

In one embodiment, referring to FIG. 1, the pixel circuit may also include a threshold compensation transistor T5 and a first initialization transistor T4. The first terminal of the threshold compensation transistor T5 may be connected to one terminal of the driving transistor T3, and the second terminal of the threshold compensation transistor T5 may be connected to the gate of the driving transistor T3. The first terminal of the first initialization transistor T4 may be used to connect the first initialization signal Vref1, and the second terminal of the first initialization transistor T4 may be connected to the gate of the driving transistor T3.

Referring to FIG. 10 and FIG. 14, the first power line 41 may include a third region R3 that at least partially covers the threshold compensation transistor T5 and the first initialization transistor T4 in the first direction. The third region R3 of the first power line 41 may cover the threshold compensation transistor T5 and the first initialization transistor T4 in the first direction, thereby isolating the threshold compensation transistor T5 and the first initialization transistor T4 from the outside environment. The compensation transistor T5 and the first initialization transistor T4 may be oxide transistors (Indium Gallium Zinc Oxide, IGZO). The first power line may be covered above the transistors T4 and T5 through the third region R3 of the first power line 41, which may play a light-shielding role and avoid the threshold compensation transistor T5 and the first initialization transistor T4 undergoing changes when exposed to light. Therefore, the life and stability of the threshold compensation transistor T5 and the first initialization transistor T4 may be improved, thereby improving the life and display quality of the display panel.

In this embodiment, by arranging the third region R3 of the first power line 41 in the first direction to cover the threshold compensation transistor T5 and the first initialization transistor T4, it may play a light-shielding role and avoid the threshold compensation transistor T5 and the first initialization transistor T4 to change when being exposed to light. Therefore, the life and stability of the threshold compensation transistor T5 and the first initialization transistor T4 may be improved, thereby improving the life and display quality of the display panel.

In one embodiment, referring to FIG. 13, the first power line 41 may include a fourth region R4, the pixel circuit may also include a first light-emitting control transistor T1. The first terminal of the first light-emitting control transistor T1 may be electrically connected to the driving transistor T3, and the second terminal of the first light-emitting control transistor T1 may be electrically connected to the fourth region R4 of the first power line 41. The first power line 41 in the fourth region R4 may be used to connect the first power lines 41 in two adjacent third regions R3.

Referring to FIG. 12 and FIG. 13, the first power line 41 of the fourth region R4 may be connected to the second terminal of the first light-emitting control transistor T1 to provide the power signal PVDD for the first light-emitting control transistor T1. At the same time, the fourth region R4 of the first power line 41 may also be connected to the first power line 41 in the second region R2 and the third region R3 corresponding to two adjacent pixel circuits such that the first power lines 41 in the two adjacent third regions R3 may be electrically connected together to respectively provide power signals to corresponding pixel circuits and achieve a shielding effect.

In one embodiment, by arranging the first power line 41 in the fourth region R4, the first power lines 41 in two adjacent third regions R3 may be connected, thereby realizing interoperable transmission of power signals.

In one embodiment, referring to FIG. 13, the first power line 41 may further include a fifth region R5. The second region R2 and the fifth region R5 may be electrically connected through the fourth region R4. In the second direction, the width of the first power line 41 in the fourth region R4 may be smaller than the width of the first power line 41 in the second region R2. The first region R1 and the fifth region R5 may be spaced apart in the third direction. There may be a light-transmitting area between the first region R1 and the fifth region R5.

In the second direction, the width of the first power line 41 in the fourth region R4 may be smaller than the width of the first power line 41 in the second region R2. This may be because the width of the first power line 41 in the fourth region R4 needs to be relatively small to leave a light-transmitting area between the regions surrounded by the first region R1, the fourth region R4 and the fifth region R5 such that the external ambient light may pass through the light-transmitting area and reach the circuit below. Such a design may take into account the design of touch control or the design of ambient light detection in the lower circuit. An optical sensor circuit may be provided on the lower layer of the light-transmitting area. The optical sensor circuit may include a photosensitive element, which may sense external ambient light, and may then adjust the brightness of the display product itself based on the ambient brightness to achieve a brightness adjustment effect. In other cases, strong light may be emitted through the light-transmitting area. When the user's finger touches the light-transmitting area, the screen area under the finger emits strong light, illuminating the entire finger surface. This light may be reflected by the finger and enter the screen again and may form images of the fingers on the optical sensor under the screen through the lens under the screen. The optical sensor may collect the fingerprint image and compare it with the registered fingerprint in the storage to achieve the identity authentication function, that is, the light-sensitive fingerprint recognition.

In this embodiment, by designing the width of the first power line 41 in the fourth region R4 to be smaller than the width of the first power line 41 in the second region R2 in the second direction, the first region R1 and the fifth region R5 to be arranged at intervals in the third direction, and a light-transmitting area to be between the first region R1 and the fifth region R5, the position of the light-transmitting area may be left. Accordingly, the first power line 41 may achieve the shielding effect while also leaving a light-transmitting area, and the normal operation of the underlying circuits (such as optical sensor circuits) may not be affected (

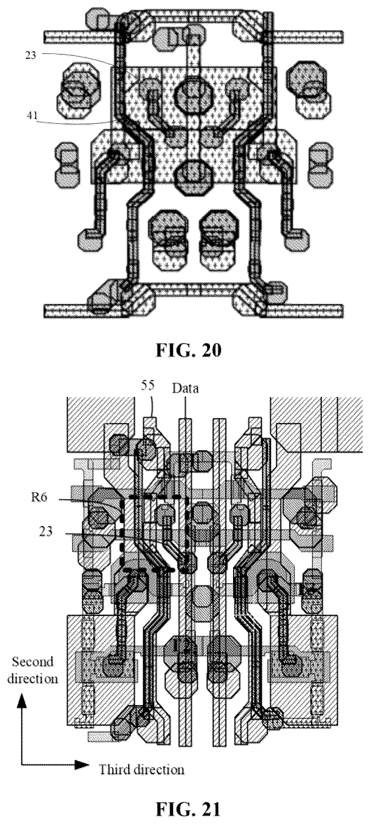

FIG. 17 is a schematic diagram of another exemplary multiple-layer stacked structure of array substrate according to various disclosed embodiments of the present disclosure. FIG. 19 is a schematic diagram of the layer structure of the second conductive layer 40. The schematic diagram of the film layer of the second conductive layer 40 shown in FIG. 19 stacked with the first conductive layer 30 in FIG. 12 is shown in FIG. 20. Compared with FIG. 13, the design of the first power line 41 in FIG. 19 may be different, and the design of other metal lines may be same as that in FIG. 13. In the direction perpendicular to the array substrate, the first power line 41 may at least partially overlap the data line Data of two adjacent pixel circuits, which may shield impact of the transition of the data signal in the data line Vdata to other signals (such as the anode signal). The first power line 41 on the second conductive layer 40 may isolate at least a part of the metal bridge line 23 and the first line segment 55 on the third conductive layer 50, and no first power line may be provided on the threshold compensation transistor T5 and the first initialization transistor T4. Thus, the costs may be reduced.

In one embodiment, referring to FIG. 14, the third conductive layer 50 may include second power lines 57 extending in the second direction and arranged in the third direction. The second power line 57 and the first power line 57 may be connected through the via hole at the position G3. It can be seen from FIG. 13 and FIG. 14 that the second power line 57 and the first power line 41 may have an overlapping area in the first direction and may be connected through a via hole.

In one embodiment, a second power line 57 may also be provided on the third conductive layer 50. The second power line 57 and the first power line 41 may be connected through a via hole at the position G3, thereby realizing the transmission of the power signal.

In one embodiment, referring to FIG. 14 and combined with FIG. 10, in a direction perpendicular to the display panel, the second power line 57 may cover at least parts of the threshold compensation transistor T5 and the first initialization transistor T4.

In one embodiment, in the direction perpendicular to the display panel, the second power line 57 may cover at least parts of the threshold compensation transistor T5 and the first initialization transistor T4, a shielding effect may be achieved on the threshold compensation transistor T5 and the first initialization transistor T4. The change of characteristics of the threshold compensation transistor T5 and the first initialization transistor T4 due to external illumination may be prevented.

FIG. 21 is a schematic diagram of a multiple layer structure of an exemplary array substrate according to various disclosed embodiments of the present disclosure. In one embodiment, as shown in FIG. 21, in the first direction, the first line segment 55 may not overlap with the metal bridge line 23. The array substrate may include a winding region R6 and a non-winding region. All regions except the winding region R6 may be regarded as the non-winding region. The area of the winding region R6 may not be limited in any way, and is only used to indicate the region where the first line segment 55 does not overlap with the metal bridge line 23.

In the third direction, the distance between the first line segment 55 and the orthographic projection of the metal bridge line 23 on the first conductive layer 20 may be d. When d>0, the display abnormality may be effectively reduced.

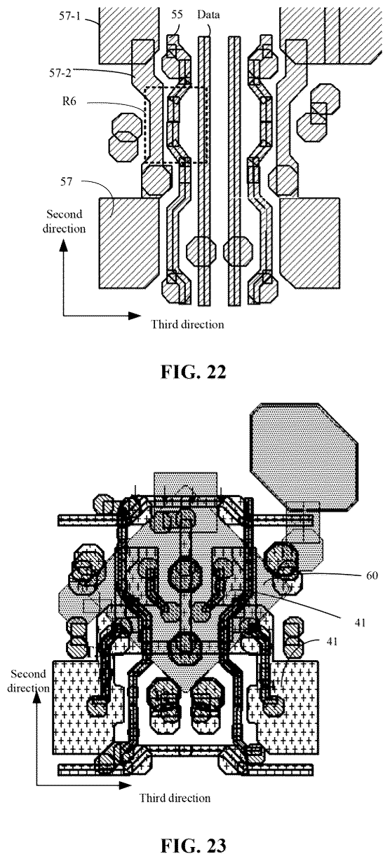

FIG. 22 is a schematic diagram of another exemplary third conductive layer according to various disclosed embodiments of the present disclosure. FIG. 12 is a schematic diagram of the film layer where the metal bridge line 23 is located. As shown in FIG. 12 and FIG. 22, the array substrate may include a winding region R6 and a non-winding region. All regions except the winding region R6 may be considered as the non-winding region. The metal bridge line 23 may be located in the winding region R6. In FIG. 22, the first line segment 55 in the winding region R6 may be bent to bypass the arrangement region of the metal bridge wire 23 such that the distance between the first line segment 55 and the metal bridge wire 23 may be d, and d>0.

In the third direction, the distance between the first line segment 55 and the orthographic projection of the metal bridge line 23 on the substrate may be d, and d>0. Accordingly, the first line segment 55 may avoid the design of the metal bridge line 23, which may greatly reduce the coupling capacitance between the first line segment 55 and the metal bridge line 23. In such a configuration, even if a signal jump occurs on the first line segment 55, its impact on the potential of the metal bridge line 23 may be substantially small.

In one embodiment, in the third direction, the distance d between the first line segment 55 and the metal bridge line 23 may be greater than 0.5 micron, while satisfying process controllability and taking into account the resolution of the display panel, the first line segment 55 may maintain a certain distance from the metal bridge line 23, thereby greatly reducing the coupling capacitance between the first line segment 55 and the metal bridge line 23, making the potential of the metal bridge line 23 more stable, and improving the stability of the current in the pixel circuit. Accordingly, the stability of the display screen on the array substrate may be ensured.

Further, as shown in FIG. 22, for the same pixel circuit, the orthographic projections of the data line Data, the first line segment 55, and the second power line 57 on the substrate may be arranged in sequence in the third direction. In the winding region R6, in the third direction, the distance between the first line segment 55 and the orthographic projection of the second power line 57 on the substrate may be smaller than the distance between the first line segment 55 and the orthographic projection of the data line Data on the substrate. Placing the first line segment 55 close to the second power line 57 and away from the Data line may, on the one hand, reduce the crosstalk between the first line segment and the data line Data. When the distance is closer, the crosstalk may become more serious. On the other hand, relative to Data line, the second power line may have a larger variable space and may be designed adaptively with the first line segment 55.

In this embodiment, by designing the first line segment 55 to have no overlap with the metal bridge line 23 in the first direction, and in the third direction, the distance between the orthographic projection of the first line segment 55 on the first conductive layer 20 and the metal bridge line 23 may be d, and d>0, thereby greatly reducing the coupling capacitance between the first line segment 55 and the metal bridge line 23, making the potential of the metal bridge line 23 more stable, and improving the stability of the current in the pixel circuit. Thus, the stability of the display screen of the array substrate may be ensured.

In one embodiment, the width of the second power line 57 in the winding region R6 may be less than or equal to the width of the second power line 57 in the non-winding region.

As mentioned above, the first line segment 55 may be appropriately bent, that is, wound, to avoid the metal bridge line 23. To avoid interference with the normal data line Data, the first data line 55 may be directed toward the metal bridge line 23. The second power line 57 may be arranged adjacent to the second power line 57. However, when the distance between the two is too close, it may increase the difficulty of the process operation, such as increasing the difficulty of etching. Therefore, the width of the second data line 57 in the winding region or adjacent to the winding region may be reduced such that the width of the second power line in the winding region may be less than or equal to the width of the second power line in the non-winding region. On the one hand, the distance between the second power line 57 and the first line segment 55 may be increased to reduce the etching difficulty. On the other hand, the reduction in the width of the second power line 57 in the winding region may not bring too much voltage drop problem to the transmitted power signal.

In one embodiment, by designing the width of the second power line 57 in the winding region R6 to be smaller than the width of the second power line 57 in the non-winding region, the distance between the second power line 57 and the first line segment 55 may be increased; the difficulty of etching may be reduced; and the operability of the process may be increased.

In one embodiment, in the winding region, in the third direction, the distance between the first line segment 55 and the orthographic projection of the second power line 57 on the substrate may be greater than 2 microns. Because the first line segment 55 and the second power line 57 may be located on the same metal layer, setting the above values may reduce the etching difficulty and improve the reliability of the process.

Referring to FIG. 15, the first region R1 of the first power line 41 may cover the metal bridge line 23. Combined with the design of the first line segment 55 in the winding region R6 shown in FIG. 21, on the one hand, a certain distance may be maintained between the first line segment 55 and the metal bridge line 23, thereby greatly reducing the coupling capacitance between the first line segment 55 and the metal bridge line 23. At the same time, the first region R1 of the first power line 41 may also play an isolation role, isolating at least parts of the metal bridge line 23 and the first line segment 55 on the third conductive layer, thereby reducing the parasitic capacitance between the metal bridge line 23 and the first line segment 55 on the third conductive layer to prevent the potential of the metal bridge line 23 from being affected by the first line segment 55 on the third conductive layer. Accordingly, the potential of the metal bridge line 23 may be more stable, the stability of the current in the pixel circuit may be improved and the stability of the display screen of the array substrate may be ensured.

FIG. 23 is a schematic diagram of the stacked structure of the anode of an exemplary array substrate according to various disclosed embodiments of the present disclosure. FIG. 21 is another schematic diagram of the stacked structure of the anode of an exemplary array substrate according to various disclosed embodiments of the present disclosure. In one embodiment, as shown in FIG. 23, the array substrate may include an anode layer 60 located on a side of the second conductive layer 40 away from the substrate. As shown in FIG. 24, the anode layer 60 may be located on the side of the third conductive layer away from the substrate. The anode layer 60 may include a first anode 61.

The second power line 57 may include a first part 57-1 and a second part 57-2 connecting adjacent first parts. In the third direction, the width of the first part 57-1 may be greater than the second part 57-2.

In the direction perpendicular to the array substrate, the first anode 61 may at least partially cover the second portion 57-2 of the second power line 57. Adjusting the overlap between the second power line and the anode on the anode layer may also ensure the flat design of the anode on the anode layer, which may be helpful to ensure that the light emitted by the first light-emitting element may have a balanced optical path and may avoid the deviation of brightness or chromaticity to ensure the display effect.

In one embodiment, in the first direction, the first power line 41 may at least partially overlap the data lines Vdata of two adjacent pixel circuits, and the anode layer 60 may further include a second anode 62. In the direction perpendicular to the array substrate, the second anode 62 may cover at least a part of the first power line 41.

In this embodiment, by designing the anode layer to be located above the first power line, the first power line may at least partially overlap with the data lines of two adjacent pixel circuits to reduce the signal interference of the data signal line on the anode layer. Accordingly, the display effect may be ensured.

The present disclosure also provides a display panel. The display panel may include any array substrate provided in the above embodiments and a light-emitting element D1.

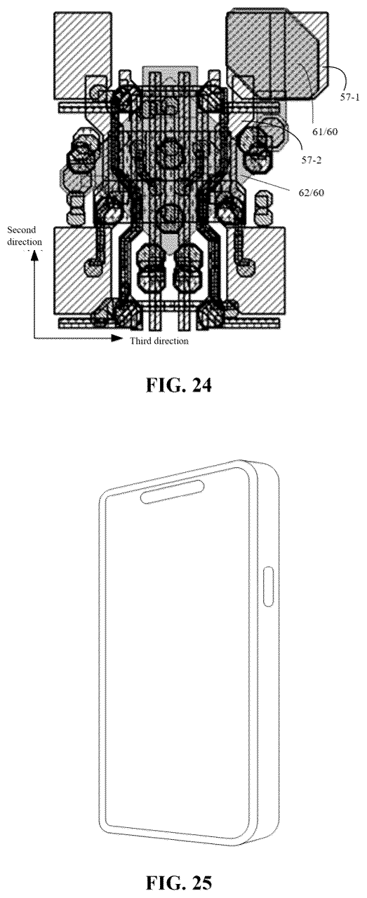

Further, the present disclosure also provides a display device. FIG. 25 is a schematic structural diagram of an exemplary display device according to various disclosed embodiments of the present disclosure. As shown in FIG. 25, the display device may include any display panel provided by the above embodiments. Therefore, the display device may also have the beneficial effects of the display panel in the above embodiments. The similarities may be understood with reference to the above explanation of the display panel, and will not be described again below.

The display device provided by the embodiments of the present disclosure may be a mobile phone or any electronic product with a display function, including but not limited to the following categories: televisions, notebook computers, desktop monitors, tablet computers, digital cameras, smart bracelets, smart glasses, vehicle-mounted displays, industrial control equipment, medical display screens, or touch interactive terminals, etc., and the embodiments of the present disclosure are not particularly limited.

In the description of this specification, reference to the terms “some embodiments”, “other embodiments”, or “ideal embodiments”, etc., may mean that a particular feature, structure, material, or characteristic described in connection with the embodiment or example is included in at least one embodiment or example of the disclosure. In this specification, schematic descriptions of the above terms do not necessarily refer to the same embodiment or example.

The technical features of the above embodiments may be combined in any way. To simplify the description, not all possible combinations of the technical features in the above embodiments are described. However, as long as there is no contradiction in the combination of these technical features, all possible combinations should be used, and may be considered to be within the scope of this disclosure.

The above-described embodiments only express several implementation modes of the present disclosure, and their descriptions are relatively specific and detailed, but they should not be construed as limiting the scope of the disclosure. It should be noted that, for those of ordinary skill in the art, several modifications and improvements can be made without departing from the concept of the present disclosure, and these all fall within the protection scope of the present disclosure. Therefore, the scope of protection of this disclosure should be determined by the appended claims.

What is claimed is:

1. An array substrate, comprising:
a substrate;
a first conductive layer above one side of the substrate;
a pixel circuit including a driving transistor and a reset bias transistor, wherein the driving transistor and the reset bias transistor are electrically connected through a metal bridge line located on the first conductive layer;
a second conductive layer located on a side of the first conductive layer away from the substrate, wherein a first power line is located on the second conductive layer; and
a third conductive layer located on a side of the second conductive layer away from the substrate, wherein a data line is located on the third conductive layer,
wherein, in a first direction perpendicular to the substrate, the first power line at least partially covers the metal bridge line.

2. The array substrate according to claim 1, comprising:
a display region; and
a non-display region surrounding the display region,
wherein:
the non-display region includes a fan-out region;
the data line includes a first data line;
the first data line is electrically connected to a fan-out line through a fan-out data line in the fan-out region;
the fan-out data line is located in the display region;
the fan-out data line includes a first line segment extending in a second direction and a second line segment extending in a third direction;
the second direction and the third direction intersect each other;
the data line extends in the second direction;
the first line segment is located on the third conductive layer;
the second line segment is connected to the third conductive layer; and
in the first direction, the first line segment at least partially overlap the first power line.

3. The array substrate according to claim 2, wherein:
in the first direction, the metal bridge line and the first line segment include an overlap region; and
the first power line includes a first region covering the overlap region.

4. The array substrate according to claim 1, further comprising:
second initialization signal lines extending in the third direction and arranged in the second direction,
wherein:
the pixel circuit further includes a second initialization transistor electrically connected to the driving transistor;
the second initialization signal line is electrically connected to the second initialization transistor;
the array substrate also includes second initialization signal connection lines extending in the second direction and arranged in the third direction; and
a second initialization signal connection line is configured to electrically connect two adjacent second initialization signal lines.

5. The array substrate according to claim 4, comprising:
reset bias signal lines extending in the third direction and arranged in the second direction,
wherein:
a reset bias signal line is electrically connected to the reset bias transistor;
the array substrate also includes reset bias signal connection lines extending in the second direction and arranged in the third direction; and
a reset bias signal connection line is used to electrically connect two adjacent reset bias signal lines.

6. The array substrate according to claim 5, wherein:
the second initialization signal connection lines and the reset bias signal connection lines are alternately arranged in a direction of a same pixel column.

7. The array substrate according to claim 1, wherein the pixel circuit further comprises:
a first light-emitting control transistor, wherein a first terminal of the first light-emitting control transistor is electrically connected to the driving transistor and a second terminal of the first light-emitting control transistor is electrically connected to the first power line.

8. The array substrate according to claim 3, wherein the first power line comprises:
a second region, wherein, in the first direction, the second region covers a channel region of the driving transistor.

9. The array substrate according to claim 8, wherein the pixel circuit further comprises:
a threshold compensation transistor, wherein a first terminal of the threshold compensation transistor is connected to a terminal of the driving transistor, and a second terminal of the threshold compensation transistor is connected to a gate of the driving transistor;
a first initialization transistor, wherein a first terminal of the first initialization transistor is used to access a first initialization signal, and a second terminal of the first initialization transistor is connected to the gate of the driving transistor; and
the first power line includes a third region, wherein, in the first direction, the third region covers the threshold compensation transistor and the first initialization transistor.

10. The array substrate according to claim 9, wherein:
the first power line includes a fourth region;
the pixel circuit further includes a first light-emitting control transistor;
a first terminal of the first light-emitting control transistor is electrically connected to the driving transistor;
a second terminal of the first light-emitting control transistor is electrically connected to the fourth region of the first power line; and
the fourth region connects two adjacent third regions.

11. The array substrate according to claim 10, wherein:
the first power line further includes a fifth region;
the second region and the fifth region are electrically connected through the fourth region;
in the second direction, a width of the first power line in the fourth region is smaller than a width of the first power line in the second region;
the first region and the fifth region are spaced apart in the third direction; and
a light-transmitting region is included between the first region and the fifth region.

12. The array substrate according to claim 2, wherein:
the third conductive layer includes second power lines extending in the second direction and arranged in the third direction; and
the second power line and the first power line are connected through a via hole.

13. The array substrate according to claim 12, wherein the pixel circuit further comprises:
a threshold compensation transistor, wherein a first terminal of the threshold compensation transistor is connected to one terminal of the driving transistor, and a second terminal of the threshold compensation transistor is connected to a gate of the driving transistor; and
a first initialization transistor, a first terminal of the first initialization transistor is used to access a first initialization signal, and a second terminal of the first initialization transistor is connected to the gate of the driving transistor,
wherein, in the first direction, the second power line covers the threshold compensation transistor and the first initialization transistor.

14. The array substrate according to claim 1, wherein:
the array substrate includes a display region and a non-display region surrounding the display region;
the non-display region includes a fan-out region;
the data line includes a first data line;
the first data line is electrically connected to a fan-out line in the fan-out region through a fan-out data line;
the non-display region is provided with a data signal driver;
the first data line is electrically connected to the data signal driver through a fan-out data line;
the fan-out data line is located in the display region;
the fan-out data line includes a first line segment extending in a second direction and a second line segment extending in a third direction;
the second direction intersects with the third direction;
the data line extends in the second direction;
the first line segment is located on the third conductive layer;
the second line segment is electrically connected to the first data line;
a distance between the first line segment and an orthographic projection of the metal bridge line on the substrate is d; and
d>0.

15. The array substrate according to claim 14, comprising:
a winding region; and
a non-winding region,
wherein:
the metal bridge line is located in the winding region;
for a same pixel circuit, orthographic projections of the data line, the first line segment, and the second power line on the substrate are arranged sequentially in the third direction; and
in the winding region, a distance between the first line segment and an orthographic projection of the second power line on the substrate is smaller than a distance between the first line segment and an orthographic projection of the data line on the substrate.

16. The array substrate according to claim 15, wherein:
a width of the second power line in the winding region is less than or equal to a width of the second power line in the non-winding region.

17. The array substrate according to claim 16, wherein:
a distance between the first line segment in the winding region and an orthographic projection of the metal bridge line on the substrate is greater than or equal to 0.5 microns.

18. The array substrate according to claim 14, comprising:
a winding region; and
a non-winding region,
wherein:
the metal bridge line is located in the winding region;
for a same pixel circuit, the data line, the first line segment, and the second power line are arranged in sequence in the third direction; and
in the winding region, and in the third direction, a distance between the first line segment and an orthographic projection of the second power line on the substrate is greater than 2 microns.

19. A display panel, comprising:
an array substrate; and
a light-emitting element,
wherein the array substrate includes:
a substrate;
a first conductive layer above one side of the substrate;
a pixel circuit including a driving transistor and a reset bias transistor, wherein the driving transistor and the reset bias transistor are electrically connected through a metal bridge line and the metal bridge line is located on the first conductive layer;
a second conductive layer located on a side of the first conductive layer away from the substrate, wherein a first power line is located on the second conductive layer; and
a third conductive layer located on a side of the second conductive layer away from the substrate, wherein a data line is located on the third conductive layer,
wherein, in a first direction perpendicular to the substrate, the first power line at least partially covers the metal bridge line.

20. A display device, comprising:
a display panel including an array substrate and a light-emitting element,
wherein the array substrate includes:
a substrate;
a first conductive layer above one side of the substrate;
a pixel circuit including a driving transistor and a reset bias transistor, wherein the driving transistor and the reset bias transistor are electrically connected through a metal bridge line and the metal bridge line is located on the first conductive layer;
a second conductive layer located on a side of the first conductive layer away from the substrate, wherein a first power line is located on the second conductive layer; and
a third conductive layer located on a side of the second conductive layer away from the substrate, wherein a data line is located on the third conductive layer,
wherein, in a first direction perpendicular to the substrate, the first power line at least partially covers the metal bridge line.
